(19) United States
(12) Patent Application Publication
(10) Pub. No.: US 2008/0014772 A1
(43) Pub. Date: Jan. 17, 2008

(54) Component mounting position correcting method and component mouting apparatus

(75) Inventors: Yutaka Ogura, Tokyo (JP); Takahiro Ohashi, Tokyo (JP)

Correspondence Address: DRINKER BIDDLE & REATH (DC), 1500 K STREET, N.W., SUITE 1100, WASHINGTON, DC, 20005-1209, US

(73) Assignee: JUKI CORPORATION

(21) Appl. No.: 11/826,259

(22) Filed: Jul. 13, 2007

(30) Foreign Application Priority Data
Jul. 14, 2006 (JP) P.2006-194441
Mar. 27, 2007 (JP) P.2007-081557
Jul. 2, 2007 (JP) P.2007-174390

(51) Int. Cl. H05K 1/00

(52) U.S. Cl. 439/83

(57) ABSTRACT

A component mounting position is corrected in accordance with a printing misalignment amount of a solder with respect to an original mounting position on a board at which a component is to be mounted. More specifically, a mounting position of a predetermined correction object component is corrected in accordance with the printing misalignment amount of the solder printed on a predetermined detection object electrode.

The present invention claims priority from Japanese Patent Applications No. 2006-194441 filed on Jul. 14, 2006, No. 2007-081557 filed on Mar. 27, 2007, and No. 2007-174390 filed on Jul. 2, 2007, the entire contents of which are incorporated herein by reference.

### TECHNICAL FILED

The present invention relates to a component mounting position correcting method and a component mounting apparatus. Specifically, the present invention relates to a component mounting position correcting method which is suitable for mounting an electronic component (also simply referred to as a component) on a board with a component mounting apparatus and is capable of accurately mounting the component on the board by detecting a printing misalignment amount of a solder with respect to a component mounting position and correcting the component mounting position in accordance with the printing misalignment. The present invention also relates to a component mounting apparatus operable to perform such a component mounting position correcting method.

### DESCRIPTION OF THE RELATED ART

A component mounting apparatus (also referred to as a component mounter) for mounting a component on a board has been known.

JP-A-5-267899 discloses a technique to accurately mount a component on a board in such a component mounting apparatus, in which a printed board is fixed on a mounting execution portion, a reference mark printed on the printed board is recognized, and a misalignment of the printed board is corrected as a preliminary preparation for mounting the component on the printed board to be carried into the component mounting apparatus.

Japanese Patent No. 3071569 discloses a solder printing inspection device, in which positions of solder creams printed on at least 3 portions of a printed circuit board are detected, and a position of a mask of a solder printer is corrected in accordance with a misalignment amount with respect to previously set printing positions.

JF-A-2002-271096, JP-A-2003-92496, and Japanese Patent No. 3656533 disclose that positions of solders printed on electrodes is recognized by an image capturing device, and that misalignment amounts of the solders with respect to a board is calculated, whereby coordinates indicating component mounting positions are corrected so as to correct the component mounting position in accordance with the misalignment amounts of the solders printed onto the board with respect to the component mounting positions on the board.

However, the technology disclosed in JP-A-5-267899 relates to a misalignment in a positioning the printed circuit board when the printed circuit board is fixed to the mounting execution portion of the component mounting apparatus, and a misalignment of a solder printed on the printed circuit board is not taken into a consideration. Therefore, a problem with regard to the printing misalignment of the solder remains.

In the technology disclosed in Japanese Patent No. 3071569, only the printing misalignment of the solder is checked, and a correction of a component mounting position is not taken into a consideration.

Further, in JP-A-2002-271096, JP-A-2003-92496, and Japanese Patent No. 3656533, images of all solder printing patterns printed on the electrodes at respective component mounting positions are captured and recognized by the image capturing device. Thus, depending on the number of mounting components or the number of the electrodes, a recognizing time is taken so that a tact time for correcting the component mounting positions is taken.

Moreover, in a multi circuit board having an assembly of a plurality of circuits, when using a function of skipping a component mounting operation on a specific circuit that is determined to be defective, the circuits are separately produced so that the misalignment of solders is recognized for each of the circuits. Thus, depending on the number of the circuits, a recognizing time is taken so that a tact time for correcting the component mounting positions is taken.

### SUMMARY OF THE INVENTION

It is an object of the present invention to correct a component mounting position efficiently in a short period of time.

According to one aspect of the invention, a method of correcting a component mounting position in accordance with a printing misalignment amount of a solder with respect to an original mounting position on a board at which a component is to be mounted, wherein the solder is printed on an electrode corresponding to the component, the method comprises:

obtaining the printing misalignment amount of the solder printed on a predetermined detection object electrode; and

correcting a mounting position of a predetermined correction object component in accordance with the printing misalignment amount.

The component mounting position may be previously stored in a mounting program as coordinates at which the component is mounted

According to another aspect of the invention, the method further comprises setting a plurality of combinations of the predetermined detection object electrode and the predetermined correction object component on the board, wherein the correcting comprises correcting the mounting position of the predetermined correction object component in accordance with a misalignment amount of a center of print positions of a pair of solders at the predetermined detection object electrode.

According to another aspect of the invention, the board is a multi circuit board on which an assembly of a plurality of circuits is arranged, wherein the correcting is performed in accordance with the misalignment amount that is common to the assembly of the plurality of circuits.

According to another aspect of the invention, a component mounting apparatus operable to mount components on a board, the component mounting apparatus comprises:

image capturing means for capturing an image of a solder printed on an electrode on which a component is to be mounted;

recognizing means for recognizing a printing misalignment amount of the solder with respect to an original mounting position of the component; and

correcting means for correcting a mounting position of a predetermined correction object component that is previously set in accordance with the printing misalignment amount of the solder printed on a predetermined detection object electrode.

According to another aspect of the invention, the component mounting apparatus further comprises setting means for setting a plurality of combinations of the predetermined detection object electrode and the predetermined correction object component on the board,

wherein the mounting position of the predetermined correction object component is corrected in accordance with a misalignment amount of a center of print positions of a pair of solders printed on the predetermined detection object electrode.

According to another aspect of the invention, the board is a multi circuit board on which an assembly of a plurality of circuits is arranged, and the correcting means corrects the mounting position in accordance with the printing misalignment amount that is common to the assembly of the plurality of circuits.

According to one or more aspects of the invention, the component mounting positions are corrected by recognizing only the printing misalignment amount of the solder at the previously set detection object electrode, without recognizing all of the misalignment amounts of the solders. Therefore, a time period of detecting a printing misalignment of the solder can be shortened. Further, in accordance with the misalignment amount of the solder at the detection object electrode, not all the mounting positions of the components are not corrected, but only the mounting position of the previously set correction object component within a certain range is corrected. Therefore, the component can be accurately mounted with respect to the printing misalignment of the solder.

For example, when a solder is reflowed with respect to a component, a component having a light weight flows to a regular mounting position along with the solder due to a surface tension. Therefore, it is preferable to correct a mounting position of the component in accordance with the printing misalignment amount of the solder. On the other hand, a heavy component does not flow along with a solder. Therefore, it is preferable to mount the component at an original position of a component electrode without correcting the mounting position of the component in accordance with the printing misalignment amount of the solder. According to one or more of aspects of the invention, a component that requires or does not require a correction of its mounting position can be treated separately, e.g. in accordance with the weight of the component as described above.

When the plurality of combinations of the detection object electrode and the correction object component, the mounting position of which is corrected in accordance with the printing misalignment amount of the solder at the detection object electrode, are set on the board, the correction of the mounting position based on the printing misalignment amount of the solder can be carried out, coping with differences in expansion or contraction at respective positions on the board.

Further, the component mounting apparatus detects the printing misalignment amount of the solder by the image capturing device of its own, thereby enabling to detect a failure in printing the solder. Therefore, an expensive solder inspection device is not separately needed.

Further, even when there is an assembly of a plurality of circuits, the common result of recognizing the printing misalignment amount of the solder can be shared by the plurality of circuits. Therefore, it is not necessary to recognize the printing misalignment amount of the solder for each of the circuits so that a time for detecting the printing misalignment of the solder can be shortened. In addition, a screen mask for printing the solder has smaller stretching property than the board. Therefore, the misalignment can be corrected accurately by recognizing the printing misalignment amount of one set of solders on the board, without recognizing the printing misalignment of the solder for each of the circuits.

### BRIEF DESCRIPTION OF THE DRAWINGS

FIG. 1 is a perspective view of a partially cutout electronic component mounter according to an exemplary embodiment of the invention;

FIG. 2 is a plane view showing an example of a board to be processed in a first exemplary embodiment of the invention;

FIG. 3 is a detailed view showing an example of an image of electrodes and solders in the first exemplary embodiment;

FIG. 4 is a flowchart of processing steps according to the first exemplary embodiment;

FIG. 5 is a plane view showing an example of a multi circuit board to be processed in a second exemplary embodiment of the invention, on which an assembly of a plurality of circuits is arranged; and

FIG. 6 is a flowchart of processing steps according the second exemplary embodiment.

### DETAILED DESCRIPTION

Hereinafter, exemplary embodiments of the invention will be described in details with reference to the drawings.

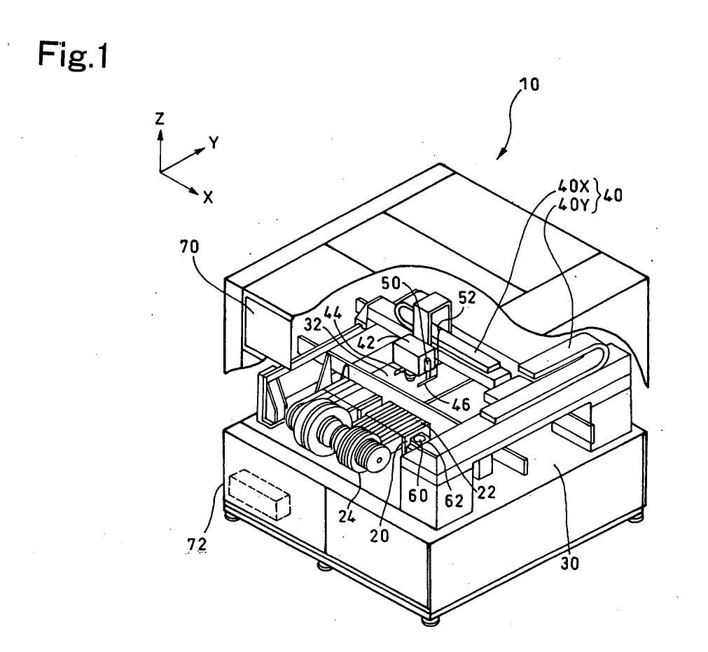

FIG. 1 shows an outline view of an electronic component mounter. The electronic component mounter 10 includes a component supplying portion 20 arranged at a front portion thereof (a left lower side in the drawing), a board delivering portion 30 extending in a direction from a left upper aide to a right lower side in the drawing slightly on a rear side from its center portion, and an XY transferring portion 40 having an X axis gantry 40X and a Y axis gantry 40Y. The board delivering portion 30 delivers a board 32 on which a component 22 is to be mounted. The XY transferring portion 40 is arranged so as to be movable toward the front portion of the electronic component mounter 10.

In the component supplying portion 20, a plurality of tape feeders 24, each storing a plurality of the components 22 therein, is arranged in lines.

A sucking head portion 42 is mounted on the XY transferring portion 40, and is movable in an up and down direction (a Z axis direction). The sucking head portion 42 includes a sucking nozzle 44 operable to suck the component 22 at the component supplying portion 20 and to mount the component 22 on the board 32.

A board recognizing camera 50 for taking an image of the board 32 from above, and an illumination device 52 for the board recognizing camera 50 are attached to a supporting member of the sucking head portion 42. A component recognizing camera 60 for taking an image of the component sucked by the sucking nozzle 44 from below, and an illumination device 62 for the component recognizing camera 60 are provided, for example, at a position on a side of the component supplying portion 20.

In addition, the sucking head portion 42 is provided with a laser unit 46 for checking presence/absence and a shape of the component sucked to the sucking nozzle 44.

An operation monitor 70 is arranged at an upper portion of the electronic component mounter 10.

A control portion 72 is arranged at a lower portion of the electronic component mounter 10, and is operable to perform an arithmetic process with respect to the images taken by the board recognizing camera 50 and the component recognizing camera 60, thereby correcting a component mounting position.

Next, a procedure in the electronic component mounter 10 according to a first exemplary embodiment will be described, in which print positions of solders printed on a plurality of electrodes are recognized when positioning the board, and printing misalignment amounts of the solders with respect to component mounting positions are detected, whereby component mounting positions are corrected.

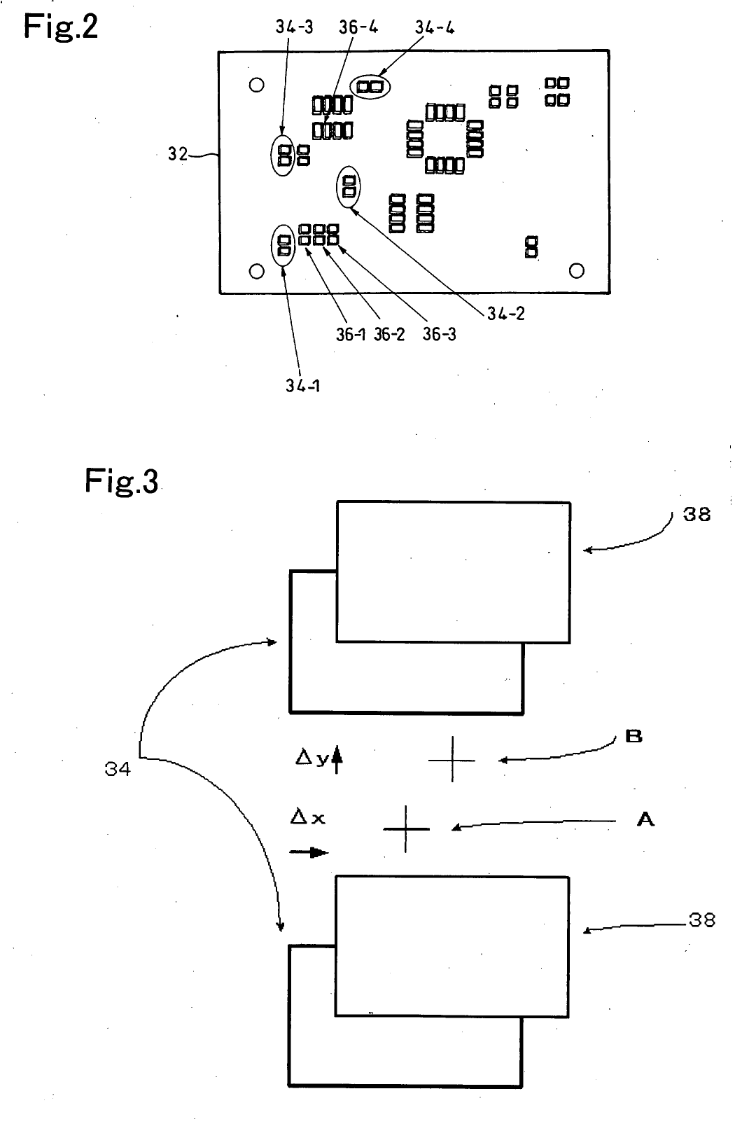

A detection object electrode, at which a printing misalignment amount of a solder is detected, is previously set by a teaching operation, or is previously registered in a mounting program as mounting coordinates. For example, on a board 32 printed with solders as shown in FIG. 2, component electrodes 34-1, 34-2 are set as detection object electrodes at which the respective printing misalignment amounts of the solders are detected. At the same time, for example, electrodes 36-1, 36-2, 36-3, 34-1, 34-2 are set as electrodes corresponding to correction object components, the mounting positions of which are corrected in accordance with a simple average value of the printing misalignment amounts detected at the electrodes 34-1, 34-2 or in accordance with ratios of the printing misalignment amounts and distances at the electrodes 34-1, 34-2 (in accordance with a distance weighted average). Similarly, component electrodes 34-3, 34-4 are set as detection object electrodes at which the respective printing misalignment amounts of the solders are detected, and electrodes 36-4, 34-3, 34-4 are set as electrodes corresponding to correction object components, the mounting positions of which are corrected in accordance with a simple average value of the printing misalignment amounts detected at the electrodes 34-3, 34-4 or in accordance with ratios of the printing misalignment amounts and distances at the electrodes 34-3, 34-4 (in accordance with a distance weighted average).

When the detection object electrodes and the electrodes corresponding to the correction object components are set as described above and a production of the board 32 is started, the board recognizing camera 50 is moved to respective positions of the previously set detection object electrodes and recognizes the printing misalignment amounts of the solders before the mounter 10 mounts the components 22. In accordance with the misalignment amounts (Δx, Δy) of the solders, the mounting positions (coordinates of the mounting position) of the previously set correction object component is corrected, and thereafter, the respective components are mounted. As exemplified in FIG. 3, the misalignment amount (Δx, Δy) may be a shift amount between a original component mounting position A and a center position B of a pair of solders 38 corresponding to the original component mounting position A. In terms of design, the original component mounting position A is a center position of a pair of component electrodes 38. Positions of the respective solders 38 may be treated as centers of gravity of the solders 38. Alternatively, positions of centers of the respective solders 38 may be calculated by detecting edges of the respective solders 38.

A correction amount obtained from the misalignment amount of between the original component mounting position A and the center position B of the pair of solders 38 is calculated in accordance with a previously set coefficient k. For example, when k=0.5, the initial component mounting position is corrected with the misalignment amount (Δx, Δy) of the solder being multiplied by 0.5. This coefficient k may be set arbitrarily.

When a plurality (of sets) of detection object electrodes is set, a simple average value may be the misalignment amount. More specifically, in the example of FIG. 2, the component mounting positions corresponding to the electrodes 36-1, 36-2, 36-3 of the correction object components and the component mounting positions corresponding to the detection object electrodes 34-1, 34-2 maybe corrected based on an average value of misalignment amounts of solders at detection object electrodes 34-1, 34-2, while the component mounting position corresponding to the electrodes 36-4 of the correction object component and the component mounting positions corresponding to the detection object electrodes 34-3, 34-4 may be corrected based on an average value of misalignment amounts of solders at the detection object electrodes 34-3, 34-4.

Meanwhile, a previously set allowable value may be referred in respect to the shift amount between the coordinates of the original component mounting position and the coordinates of the print positions of the solder, and when the shift amount exceeds the allowable value, an alarm for the printing misalignment of the solder may be output and the mounting of the components may be stopped, whereby a failure in mounting the component can be prevented beforehand.

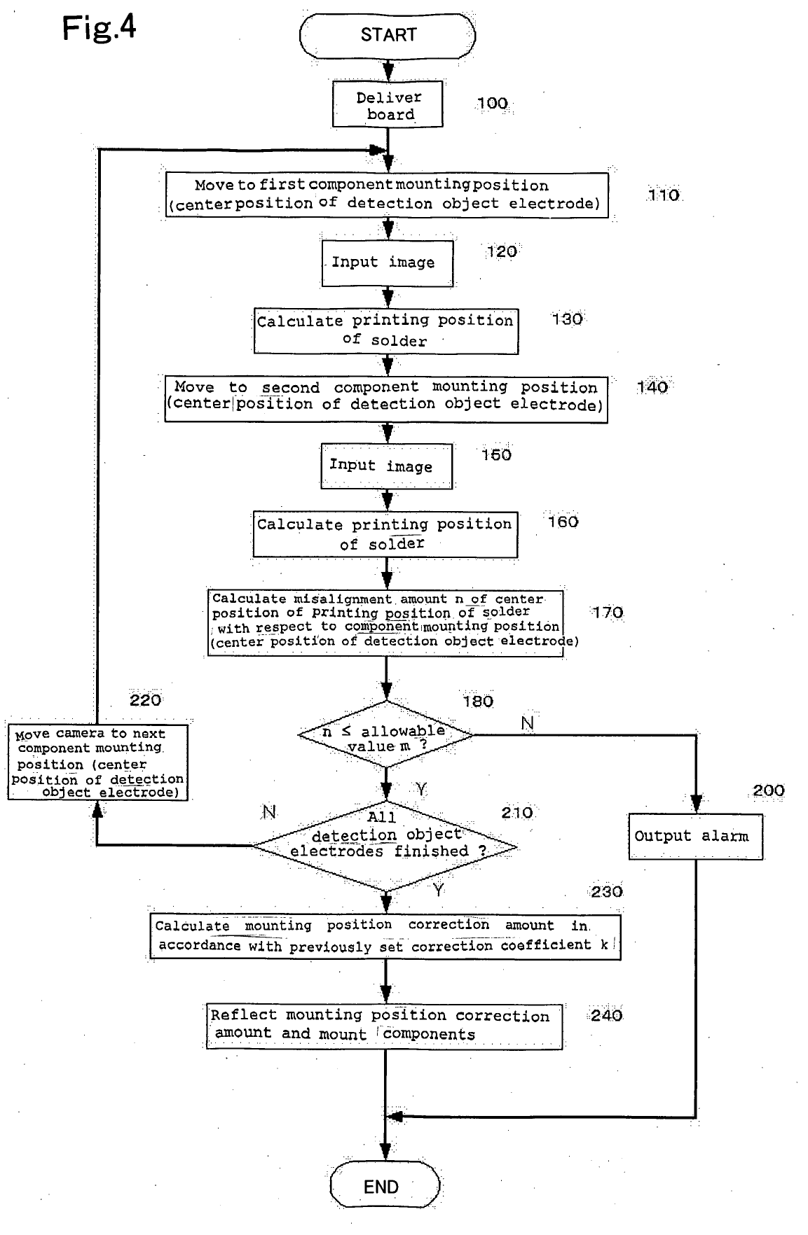

FIG. 4 shows a processing procedure in a case where there are two detection object electrodes at which printing misalignment amount of the solders are detected.

First, a board is delivered in step 100. Next, the board recognizing camera 50 is moved to a first component mounting position (a center position of one of the detection object electrodes) in step 110, an image thereof is input in step 120, and the center position of the print position of the pair solders 38 as shown in FIG. 3 is calculated in step 130.

Next, the board recognizing camera 50 is moved to a position of a second component mounting position (a center position of the other of the detection object electrodes) in step 140, an image thereof is input in step 150, and a center position of print positions of the solders is calculated in step 160.

Next, in step 170, misalignment amounts n of the solders are calculated from the two component mounting positions (the center positions of the respective detection object electrodes) and the respective center positions of the print position of the solders. Next, in step 180, it is determined whether the misalignment amounts n of the solders are equal to or smaller than an allowable value m. When the misalignment amounts n of the solder is larger than the allowable value m as a result of the determination, an alarm is output and the processing is finished in step 200.

On the other hand, when it is determined that the misalignment amounts n of the solders are equal to or smaller than the allowable value m in step 180, it is determined whether it is finished for all the registered detection object electrodes.

When it is not finished for all the registered detection object electrodes, the board recognizing camera 50 is moved to a next set position in step 220, and steps 110 through 180 are repeated.

On the other hand, when it is determined that it is finished for all the detection object electrodes set in step 210, the procedure moves on to step 230, whereby a correction amount of the component mounting position is calculated in accordance with a simple average value of the two misalignment amounts calculated in step 170 and the previously set correction coefficient k. Subsequently, the mounting operation is carried out with the correction amount being reflected in step 240.

According to an exemplary embodiment, a combination of the detection object electrodes and the correction object components is set for each of the regions on the board, thereby coping with a difference of the misalignment amount of the solder due to a difference in expansion or contraction at respective positions on the board.

Further, even within the region in which the detection object electrodes are set, components such as a heavy component or a QFP can be mounted at a original position where the electrode is placed, regardless of the misalignment amount of the solder, thereby such components can be mounted firmly.

Meanwhile, although an electrode having two terminals has been recognized in the above explanation, the object of recognition is not limited to the electrode having two terminals, and a part of an electrode having a plurality of terminals may be set.

Next, an explanation will be given of a second exemplary embodiment in which the present invention is applied to a multi circuit board on which an assembly of a plurality of circuits is arranged.

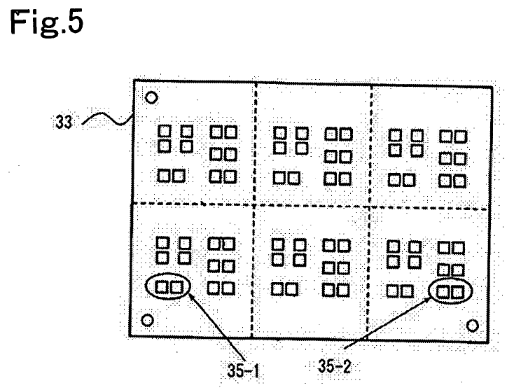

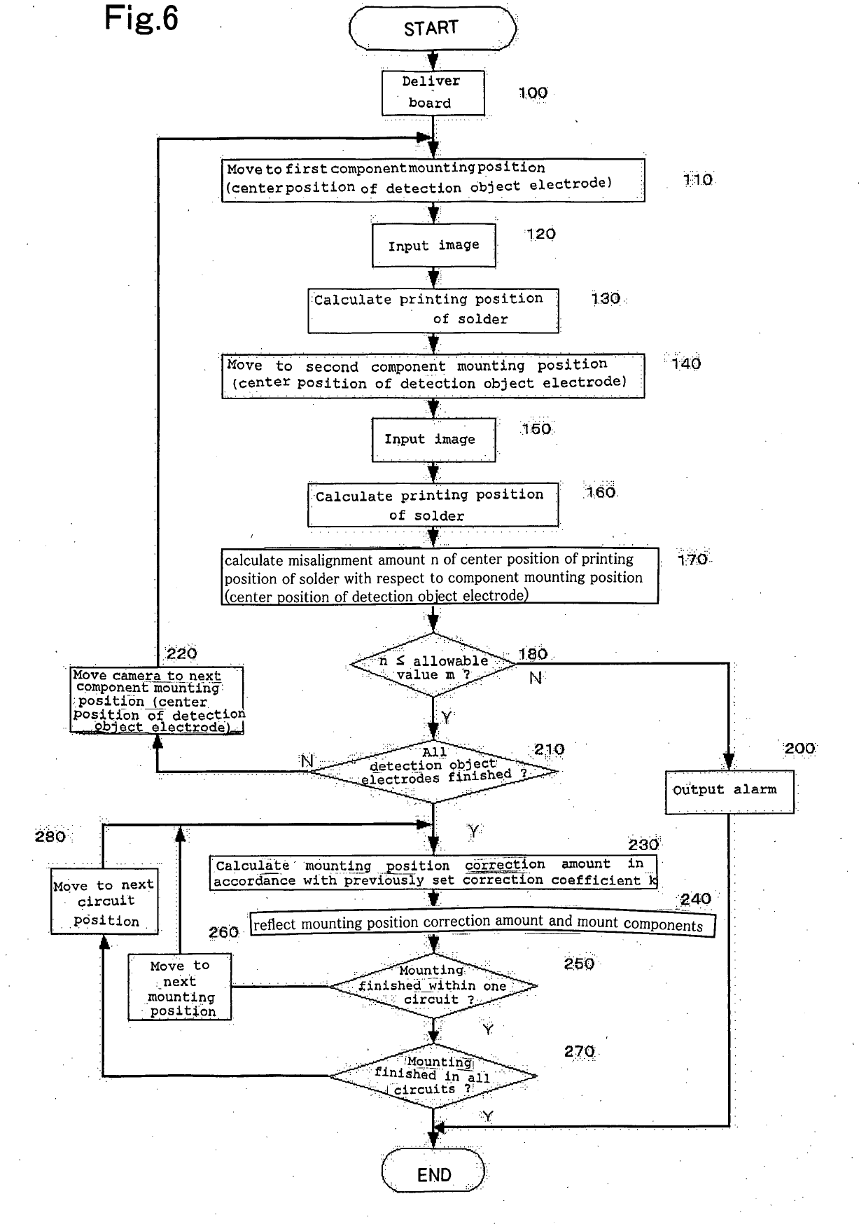

FIG. 5 shows a multi circuit board 33 on which an assembly of six circuits, two rows in a vertical direction and three rows in a horizontal direction, is arranged. FIG. 6 shows an example of a processing procedure in case where two electrodes 35-1, 35-2 are set as detection object electrodes in the multi circuit board 33.

According to the second exemplary embodiment, detection object electrodes are set so as to straddle over a plurality of circuits with reference to, e.g., a coordinate system of left lower circuit such as the electrodes 35-1, 35-2. With respect to the detection object electrodes straddling over the plurality of circuits, the steps 110 through 180 are repeated, and the solder misalignment amount is detected prior to mounting the components. When detection of the solder misalignment amount is finished, a correction amount of the component mounting position is calculated in accordance with a simple average value of the two misalignment amounts calculated in step 170 and the previously set correction coefficient k in step 230. A first component mounting position of a first circuit is obtained, and the component is mounted in step 240. Next, it is determined whether the mounting is finished within the circuit in step 250. When a result of the determination is NO, it is moved to a next component mounting position in step 260, and the steps 230 through 260 are repeated until a result of the determination in step 250 becomes YES, whereby mounting of all the components in the first circuit is finished.

When all of the components within one circuit are mounted, it is determined whether it is finished in all of the circuits in step 270. When a result of the determination is NO, it is moved to a component mounting position in a next circuit in step 280, and the steps 230 through 280 are repeated until the result of the determination in step 270 becomes YES, whereby the components are mounted in all of the circuits. Meanwhile, a common correction amount of the component mounting position may be used in the respective circuits based on the result of the detection of the misalignment amount of the solder in the steps 110 through 180.

Although the detection object electrodes 35-1, 35-2 are set so as to straddle over the plurality of circuits in the second exemplary embodiment, the detection object electrodes may be set within one circuit as in the first exemplary embodiment.

Meanwhile, the components that are actually mounted to the corrected mounting positions based on the results of detection of the misalignment amounts of the solders and coordinates thereof may be saved as a data file inside the electronic component mounter 10, so that an operator of the machine can refer to the data afterward. Further, in a system in which such data can be directly communicated with a host machine, a history of mounting the components to the mounting positions corrected based on detection of the misalignment amounts of the solders can be referred to even from a remote place.

While description has been made in connection with exemplary embodiments of the present invention, it will be obvious to those skilled in the art that various changes and modification may be made therein without departing from the present invention. It is aimed, therefore, to cover in the appended claims all such changes and modifications falling within the true spirit and scope of the present invention.

What is claimed is:

1. A method of correcting a component mounting position in accordance with a printing misalignment amount of a solder with respect to an original mounting position on a board at which a component is to be mounted, wherein the solder is printed on an electrode corresponding to the component, the method comprising:
obtaining the printing misalignment amount of the solder printed on a predetermined electrode; and
correcting a mounting position of a predetermined mounting component in accordance with the printing misalignment amount.

2. The method according to claim 1, wherein the obtaining of the printing misalignment amount comprises;
taking an image of a pair of solders printed on the predetermined electrode arranged on the board; and
recognizing a misalignment amount of a center of print positions of the pair of solders with respect to the original mounting position.

3. The method according to claim 1, further comprising setting a plurality of combinations of the original mounting position and the predetermined mounting component on the board, wherein the correcting comprises correcting the mounting position of the predetermined mounting component in accordance with a misalignment amount of a center of print positions of a pair of solders.

4. The method according to claim 1, wherein the board is a multi circuit board on which an assembly of a plurality of circuits is arranged, wherein the correcting is performed in accordance with the misalignment amount that is common to the assembly of the plurality of circuits.

5. The method according to claim 2, wherein the board is a multi circuit board on which an assembly of a plurality of circuits is arranged, wherein the correcting is performed in accordance with the misalignment amount that is common to the assembly of the plurality of circuits.

6. A component mounting apparatus operable to mount components on a board, the component mounting apparatus comprising:
image capturing means for capturing an image of a solder printed on an electrode on which a component is to be mounted;
recognizing means for recognizing a printing misalignment amount of the solder with respect to an original mounting position of the component; and
correcting means for correcting a mounting position of a predetermined mounting component that is previously set in accordance with the printing misalignment amount of the solder.

7. The component mounting apparatus according to claim 6, further comprising setting means for setting a plurality of combinations of the original mounting position and the predetermined mounting component on the board,
wherein recognizing means recognizes the printing misalignment amount of the solder as a misalignment amount of a center of print positions of a pair of solders with respect to the original mounting position, and
the correcting means corrects the mounting position of the predetermined mounting component in accordance with the misalignment amount of the center of the print positions of the pair of solders.

8. The component mounting apparatus according to claim 6, wherein the board is a multi circuit board on which an assembly of a plurality of circuits is arranged, and the correcting means corrects the mounting position in accordance with the printing misalignment amount that is common to the assembly of the plurality of circuits.

9. The component mounting apparatus according to claim 7, wherein the board is a multi circuit board on which an assembly of a plurality of circuits is arranged, and the correcting means corrects the mounting position in accordance with the misalignment amount that is common to the assembly of the plurality of circuits.

10. A method of correcting a component mounting position in accordance with a printing misalignment amount of a solder with respect to an original mounting position on a board at which a component is to be mounted, wherein the solder is printed on an electrode corresponding to the component, the method comprising:
obtaining the printing misalignment amount of the solder printed on a predetermined detection object electrode; and
correcting a mounting position of a predetermined correction object component in accordance with the printing misalignment amount.

11. The method according to claim 10, wherein the obtaining of the printing misalignment amount comprises:
taking an image of a pair of solders printed on the predetermined detection object electrode arranged on the board; and
recognizing a misalignment amount of a center of print positions of the pair of solders with respect to the original mounting position corresponding to the predetermined detection object electrode.

12. The method according to claim 10, further comprising setting a plurality of combinations of the original mounting position corresponding to the predetermined detection object electrode and the predetermined correction object component on the board, wherein the correcting comprises correcting the mounting position of the predetermined correction object component in accordance with a misalignment amount of a center of print positions of a pair of solders at the predetermined detection object electrode.

13. The method according to claim 10, wherein the board is a multi circuit board on which an assembly of a plurality of circuits is arranged, wherein the correcting is performed in accordance with the misalignment amount that is common to the assembly of the plurality of circuits.

14. The method according to claim 11, wherein the board is a multi circuit board on which an assembly of a plurality of circuits is arranged, wherein the correcting is performed in accordance with the misalignment amount that is common to the assembly of the plurality of circuits.

15. A component mounting apparatus operable to mount components on a board, the component mounting apparatus comprising:
image capturing means for capturing an image of a solder printed on an electrode on which a component is to be mounted;
recognizing means for recognizing a printing misalignment amount of the solder with respect to an original mounting position of the component; and
correcting means for correcting a mounting position of a predetermined correction object component that is previously set in accordance with the printing misalignment amount of the solder printed on a predetermined detection object electrode.

16. The component mounting apparatus according to claim 15, further comprising setting means for setting a plurality of combinations of the original mounting position corresponding to the predetermined detection object electrode and the predetermined correction object component on the board,
wherein the mounting position of the predetermined correction object component is corrected in accordance with a misalignment amount of a center of print positions of a pair of solders printed on the predetermined detection object electrode.

17. The component mounting apparatus according to claim 15, wherein the board is a multi circuit board on which an assembly of a plurality of circuits is arranged, and the correcting means corrects the mounting position in accordance with the printing misalignment amount that is common to the assembly of the plurality of circuits.

18. The component mounting apparatus according to claim 16, wherein the board is a multi circuit board on which an assembly of a plurality of circuits is arranged, and the correcting means corrects the mounting position in accordance with the misalignment amount that is common to the assembly of the plurality of circuits.
